(19) United States
(12) Patent Application Publication
(10) Pub. No.: US 2024/0051051 A1
(43) Pub. Date: Feb. 15, 2024

(54) ULTRA-THIN SOLDERING GASKET AND PREPARATION METHOD THEREFOR, SOLDERING METHOD, AND SEMICONDUCTOR DEVICE

(71) Applicant: NINGBO S J ELECTRONICS CO., LTD., Zhejiang (CN)

(72) Inventors: Fay HUA, Zhejiang (CN); Mina YAGHMAZADEH, Zhejiang (CN)

(73) Assignee: NINGBO S J ELECTRONICS CO., LTD., Zhejiang (CN)

(21) Appl. No.: 18/258,143

(22) PCT Filed: Dec. 13, 2021
(86) PCT No.: PCT/CN2021/137559

§ 371 Date: Jun. 16, 2023

(30) Foreign Application Priority Data
Dec. 16, 2020 (CN) 202011493022.8

(51) Int. Cl. B23K 3/08; B23K 1/08; B23K 1/00; H01L 23/00

(52) U.S. Cl. CPC B23K 3/08; B23K 1/08; B23K 1/0016; H01L 24/83; H01L 24/29; B23K 2101/40

(57) ABSTRACT

Embodiments of the present invention relate to the field of soldering sheets, and provided therein are an ultra-thin soldering gasket and a preparation method therefor, a soldering method, and a semiconductor device. The ultra-thin soldering gasket comprises: an internal support structure and a solder layer which covers a surface of the internal support structure, the solder layer being formed by uniformly attaching a solder liquid to the surface of the internal support structure. The preparation method for an ultra-thin soldering gasket comprises the following steps: immersing an internal support structure that has passed through a surface treatment process into a solder liquid, then removing same, and cooling. The soldering method based on the ultra-thin soldering gasket comprises: placing an ultra-thin soldering gasket between soldering surfaces to be soldered, and then performing reflux soldering to form a semiconductor device. The ultra-thin soldering gasket is flat and is not warped, solders are uniform, the minimum thickness of a single layer is only five micrometers, and high-accuracy soldering requirements can be met.

### CROSS-REFERENCE TO RELATED APPLICATION(S)

This application claims priority to Chinese Patent Application No. 202011493022.8 filed Dec. 16, 2020, the disclosure of which is incorporated herein by reference in its entirety.

### TECHNICAL FIELD

The present application relates to the field of soldering gaskets, and especially, to an ultra-thin soldering gasket, a preparation method therefor, a soldering method, and a semiconductor device.

### BACKGROUND

With the continuous advancement and development of the era of 5G and big data, the demand for large-scale chips with high power, high performance and high integration has been increased, and higher requirements have also been put forward for the packaging method of chips. In the surface mount technology (SMT) of large modules, or in the packaging process of large chips, large-area soldering is required. In this technical field, the soldering gasket is generally used to achieve the large-area soldering with high yield and uniformity.

However, some issues frequently come up during the use of the conventional soldering gasket composed of solder, such as inclined soldering surface and uneven soldering thickness. Due to the temperature change as well as the thermal expansion and contraction of the soldering modules, the stress is concentrated at the edge of the thinnest soldering region, which results in fractures and early failure of products. In order to solve the above problems, the solder layer is combined with metal mesh embedded therein to form a solder sheet with metal mesh. The metal mesh can be used as a support sheet to reduce the inclination and unevenness of the soldering surface to a certain extent. However, the conventional solder sheet with metal mesh is formed by pressing and combining the solder layer and the metal mesh, and the single-layer thickness of the solder strip is relatively large, which cannot meet the needs of high-density soldering. Besides, the solder strip needs to be rolled into a roll for storage, and might be warping after being cut. During reflow soldering, the uneven solder strip is prone to generate air holes, which cannot guarantee the quality of high-precision soldering.

### SUMMARY

Embodiments of the present application provide an ultra-thin soldering gasket, a preparation method therefor, a soldering method, and a semiconductor device. The gasket is flat and non-warping, the solder material is uniform, and the minimum single-layer thickness is only 5 μm, which can meet the needs of high-precision soldering.

Some embodiments of the present application provide an ultra-thin soldering gasket, and the ultra-thin soldering gasket can include an internal support structure and a solder layer which covers the surface of the internal support structure, in which the solder layer can be formed by uniformly coating a solder liquid to the surface of the internal support structure, and the solder layer has a lower melting point than the internal support structure.

In the above technical solution, the ultra-thin soldering gasket can include an internal support structure and a solder layer which covers the surface of the internal support structure, the solder layer is formed by uniformly coating a solder liquid with a certain thickness to the surface of the internal support structure, and the obtained ultra-thin soldering gasket is flat and non-warping; by introducing the internal support structure, a solder layer with a large thickness can be separated into a solder layer with a small thickness, and the internal support structure can also provide support function during reflow soldering. The solder layer is allowed to melt but not the internal support structure, which thus relieves the un-uniformity of ultra-thin soldering gasket during reflow soldering. The ultra-thin soldering gasket can guarantee thickness uniformity for large-area soldering and improve product reliability.

In some embodiments, the internal support structure can be a flat support sheet; optionally, a thickness of the support sheet can be 3-450 μm.

In the above technical solution, the application adopts a flat support sheet as the support structure, and the obtained ultra-thin soldering gasket is flat and non-warping; the solder layer is formed by coating the solder liquid, which can give a solder layer with a sufficiently small thickness, and the solder is uniform, which can meet the needs of high-precision soldering.

In some embodiments, the ultra-thin soldering gasket has a flat structure; optionally, a single-layer thickness of the ultra-thin soldering gasket is 10-1000 μm.

In the above technical solution, the ultra-thin soldering gasket with the flat structure can avoid warping caused by the crooked product, and thus each soldering point of the ultra-thin soldering gasket has the same condition, and the high-precision soldering can be realized. In addition, the minimum thickness of the ultra-thin soldering gasket, which includes the solder layer formed on the surface of the support sheet by coating solder liquid, can be only 10 μm. Due to the process difference, the thickness of the ultra-thin soldering gasket is inevitably smaller than the solder strip with metal mesh which is obtained by combining the solid solder layer with metal mesh directly.

In some embodiments, a material of the internal support structure is metal; optionally, the material of the internal support structure is one of copper, copper alloy, nickel alloy, iron alloy, iron-nickel alloy, iron-nickel-cobalt alloy and stainless steel.

In the above technical solution, the material of the commonly used metal support sheet can be copper, copper alloy, nickel alloy, iron alloy, iron-nickel alloy, iron-nickel-cobalt alloy and stainless steel, etc, which can avoid melting under the usual process temperature of reflow soldering, realizes support effect, and is suitable for various packaging conditions.

In some embodiments, the support sheet can be an imperforate support sheet.

In the above technical solution, the imperforate support sheet can guarantee the flatness, and thus can be coated with the solder liquid to form a flat ultra-thin soldering gasket. The woven metal mesh is avoided to use, because it has uneven surface and cannot give a flat gasket.

In some embodiments, the support sheet can be a perforated support sheet, and the perforated support sheet can be formed by opening holes on an imperforate support sheet.

In the above technical solution, the perforated support sheet formed by opening holes on the imperforate support sheet can guarantee the flatness, and thus can be coated with the solder liquid to form a flat ultra-thin soldering gasket. Or the woven metal mesh can be used, which can obtain flatness by roller pressing and coated with the solder liquid to form a flat ultra-thin soldering gasket. Moreover, the support sheet with holes or mesh holes is convenient for coating the solder liquid, and the solder amount of the ultra-thin soldering gasket can be increased by filling the solder liquid in the holes, which guarantees the tight integration of the support sheet and the solder layer.

In some embodiments, a hole diameter of the hole can be less than 200 μm, and a shape of the hole can be a triangle, a square, a rectangle, a hexagon or an irregular shape. In the above technical solution, the shapes of the holes are flexible and diverse.

In some embodiments, the support sheet can be a mesh support sheet or any continuous support structure; optionally, the support sheet or the support structure can be a mesh support sheet woven from metal wires of different diameters or woven from metal wires of different diameters and spherical structures.

In the above technical solution, the woven patterns can be flexible and diverse, and the maximum interspace can be 200 μm.

In some embodiments, a solder can be a solderable material; optionally, the solder can be selected from one of tin, a tin-based solder, indium, an indium-based solder, gallium, a gallium-based solder, a tin-bismuth solder, a tin-indium solder and other soldering materials.

In the above technical solution, the solder material is easy to form a solder liquid and a solder layer, and the solder material is melted at the usual process temperature of reflow soldering to realize soldering, which is suitable for various packaging conditions.

Some other embodiments of the present application provide a preparation method for the ultra-thin soldering gasket provided by the embodiment, and the preparation method for the ultra-thin soldering gasket can include the following steps: immersing the internal support structure which has been subjected to a surface treatment process in a solder liquid, and then removing and cooling the same.

In the above technical solution, by immersing the internal support structure in a solder liquid and then removing and cooling the same, a sufficiently small thickness of the solder layer can be obtained, and a flat ultra-thin soldering gasket with uniform solder can be obtained. The ultra-thin soldering gasket can be used directly or after being cut. Compared with those which are rolled over into a roll and then cut into specific specifications at the application site, the ultra-thin soldering gasket has better flatness and shows uniformity when applied to soldering.

In some embodiments, the internal support structure can be a flat support sheet, and the support sheet is immersed in the solder liquid by pushing the support sheet into the solder liquid along the direction perpendicular to the surface of the solder liquid, and an immersion time is selected from one second to a plurality of hours according to different internal support structures and solders;
and/or the surface treatment process of the support sheet can includes the following steps in sequence: cleaning with a cleaning liquid, drying, activating, water washing, solvent wetting and drying; optionally, the cleaning liquid is selected from one of IPA, ethanol, methane, acetone and other metal cleaning liquids; an acid-washing activation liquid used in the activating is an organic acid and/or an inorganic acid.

In the above technical solution, by immersing the support sheet according to the above immersion approach, the solder liquid can be uniformly coated on the surface of the support sheet; the support sheet after the above surface treatment can contact the molten solder liquid thoroughly, and the solder liquid is uniformly coated to the surface of the support sheet, which can guarantee no voids and thereby no air holes during the soldering.

In some embodiments, two or more support sheets are stacked together and immersed in the solder liquid at the same time, and then removed out and cooled;
or the support sheet is repeatedly immersed in the solder liquid for a plurality of times, and then removed out and cooled.

In the above technical solution, the above method can produce a relatively thick soldering gasket.

In some embodiments, the method can further include roller pressing.

In the above technical solution, roller pressing can be used to flatten the surface and achieve the expected thickness of the soldering gasket.

Some other embodiments of the present application provide a soldering method based on the ultra-thin soldering gasket provided by the embodiment, which includes placing the ultra-thin soldering gasket between soldering surfaces to be soldered, and then performing reflow soldering to form a packaging structure.

In the above technical solution, the ultra-thin soldering gasket is flat and non-warping, the solder material is uniform. When placed between soldering surfaces to be soldered for performing reflow soldering, for example, between the component to be packaged and the substrate, the ultra-thin soldering gasket has the same condition at all the soldering points that contact with the component to be packaged and the substrate, thereby realizing the high-precision soldering between the component to be packaged and the substrate, and achieving the packaging.

In some embodiments, two or more ultra-thin soldering gaskets are used by stacking together.

In the above technical solution, one ultra-thin soldering gasket can be used singly, which meets the needs of high-precision soldering, or a plurality of the gaskets can be used by stacking together, the application range of which is wide.

In some embodiments, the soldering surface is a metal surface, and optionally, the metal surface is one of copper, nickel/gold and other solderable metals.

Some other embodiments of the present application provide a semiconductor device, which can include a package structure soldered using the ultra-thin soldering gasket provided by the embodiments.

In the above technical solution, the semiconductor device has a wide application range and good stability.

In some embodiments, the semiconductor device is an integrated circuit chip package, and the semiconductor device is used in soldering a chip and a board, a chip and a chip, a board and a board, a module and a module, a chip and a module, or a board and a module together, or soldering any combination of a chip, a module, a board and a heat sink together:
or the semiconductor device is a heat dissipation module of the integrated circuit chip package, and the semiconductor device is used in soldering a chip and a heat dissipation plate together, or the semiconductor device is an IGBT module.

In the above technical solution, the IGBT module meets the chip requirements of high power, high performance and high integration.

### BRIEF DESCRIPTION OF DRAWINGS

In order to explain the technical solutions in embodiments of the present application more clearly, the accompanying drawing used in embodiments of the present application is introduced below briefly. It should be understood that the following drawing only shows some embodiments of the present application, and therefore, it should not be regarded as a limitation of the scope. For those skilled in the art, other related drawings can also be obtained based on these drawings without any creative effort.

FIG. 1 is a process flow diagram of a preparation method for an ultra-thin soldering gasket provided by an embodiment of the present application.

Reference list: 100—solder liquid; 200—support sheet; 300—composite support sheet.

### DETAILED DESCRIPTION

For more clear objects, technical solutions and advantages of embodiments of the present application, the technical solutions in embodiments of the present application will be described clearly and completely below. The embodiments without specific conditions indicated are carried out according to the conventional conditions or the conditions suggested by the manufacturer. The reagents or instruments without manufacturers indicated are the conventional products that can be purchased from the market.

An ultra-thin soldering gasket, a preparation method therefor, a soldering method, and a semiconductor device in embodiments of the present application are specifically described below.

An embodiment of the present application provides an ultra-thin soldering gasket, and the ultra-thin soldering gasket includes an internal support structure, which is generally a flat support sheet, and a solder layer which covers the surface of the internal support structure and can infiltrate into the inside of the internal support structure. The solder layer is formed by uniformly coating a solder liquid to the surface of the internal support structure, and the solder layer has a lower melting point than the internal support structure. The ultra-thin soldering gasket in this embodiment can have a flat structure; a single-piece thickness of the ultra-thin soldering gasket can be 5 μm-1 mm, and at least 5 μm. For example, the single-piece thickness can be 10 μm, 20 μm, 30 μm, 40 μm, 50 μm, 100 μm, 200 μm, 300 μm, 500 μm, 1 mm, etc. The single-piece thickness of the ultra-thin soldering gasket in the present application depends on a thickness and a preparation process of the support sheet. At present, ultra-thin soldering gaskets with the thickness of 40-300 μm have been actually produced, and ultra-thin soldering gaskets with the thickness of 30-40 μm can be prepared experimentally.

In order to ensure the support effect, a thickness of the support sheet can be 3-450 μm, and generally, the thickness is more than or equal to 3 μm, such as 3 μm, 5 μm, 8 μm, 10 μm, 50 μm, 100 μm, etc. In some embodiments of the present application, the internal support structure (support sheet) is a flat plate-like (sheet-like) structure. The internal support structure (support sheet) is not limited to metal materials, but can also be other materials that provide support function during soldering. Generally, a material of the internal support structure (support sheet) is metal. In principle, any metal can be selected as the support metal, and the material of the commonly used support sheet can be copper, copper alloy, nickel alloy, iron alloy, iron-nickel alloy, iron-nickel-cobalt alloy and stainless steel.

The support sheet can be a perforated support sheet, or even an imperforate support sheet. The perforated support sheet is formed by opening a hole on an imperforate support sheet. A hole diameter of the hole is less than 200 μm, and a shape of the hole can be any form, such as a triangle, a square, a rectangle, a hexagon or even an irregular shape. The shape of the hole can be designed according to the specific application. The number of the hole is not limited and can be customized according to the specific use scene. Correspondingly, the hole of the perforated support sheet can be opened in a manner of punching, molding or laser drilling. The perforated support sheet can also be a mesh support sheet or any continuous support structure. As an embodiment, the support sheet or the support structure is a mesh support sheet woven from metal wires of different diameters or woven from metal wires of different diameters and spherical structures.

Generally, the solder can be a solder material. In principle, any solderable material with a melting point lower than that of the support metal can be selected as the soldering metal. The commonly used solder is selected from one of an alloy system, such as Sn, Sn—Ag, Sn—Cu, Sn—Ag—Cu, Sn—Pb(Ag), Sn—Bi, Sn—In, or other soldering materials. Correspondingly, the solder liquid is a Sn—Ag—Cu (tin-aluminum-copper) system, a Sn—Pb system, a Sn—Bi system or a Sn—In system, etc.

In the process of reflow soldering, a certain process temperature is required to allow the solder layer but not the internal support structure (support sheet) to melt. To ensure that the ultra-thin soldering gasket can satisfy the common reflow soldering, the liquidus temperature of the internal support structure (support sheet) is usually greater than 500° C., while the solidus temperature of the solder layer is less than 210° C., which can meet the needs of reflow soldering.

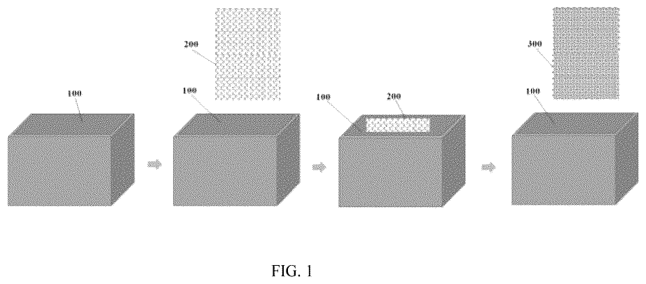

As shown in FIG. 1, for example, in a case where a support sheet 200 is used as the internal support structure, an embodiment of the present application provides a preparation method for the ultra-thin soldering gasket, and the preparation method for the ultra-thin soldering gasket includes the steps below.

Step S1: a solder is heated to 230-320° C. and melted to form a solder liquid 100.

Step S2: the support sheet 200 is subjected to a surface treatment process, the specific process of which includes the following steps in sequence: ultrasonic cleaning with a cleaning liquid, drying, acid washing for activating, water washing, IPA wetting and drying, in which the cleaning liquid is selected from one of IPA, ethanol, methane, acetone and other metal cleaning liquids; an acid-washing activation liquid used in the acid washing for activating can be selected from various organic acid or inorganic acid, or a mixed solution of various organic acid or inorganic acid.

Then, the support sheet 200 after the surface treatment process is immersed in the solder liquid 100 and kept for a certain time. Generally, a mechanical arm is used to hold the support sheet 200, and push the support sheet 200 with a certain speed, for example, 1-24 m/s, into the solder liquid 100 along the direction perpendicular to the surface of the solder liquid, and an immersion time can be selected from one second to a plurality of hours according to different materials, such as 1 s-60 min. In another embodiment, the solder liquid 100 can also be vibrated or flowed by a stirring rod at the same time, or the support sheet 200 can be moved back and forth or left and right to ensure that the solder liquid 100 fully coats to the support sheet 200. The above casting process ensures that the entire support sheet 200 is in contact with the solder liquid 100, and the solder liquid 100 fills the holes of the support sheet 200.

In the above process, two or more support sheets can be stacked together and immersed in the solder liquid at the same time, and then removed out and cooled to produce a relatively thick soldering gasket; Or the support sheet can be repeatedly immersed in the solder liquid for a plurality of times, and then removed out and cooled to produce a relatively thick soldering gasket; Or two or more support sheets can be stacked together and repeatedly immersed in the solder liquid for a plurality of times, and then removed out and cooled to produce a relatively thick soldering gasket.

Step S3: The composite support sheet 300 (the support sheet 200 with the solder liquid 100 coated on the surface) is taken out and cooled.

Generally, after the above process, a flat, uniform, non-warping ultra-thin soldering gasket can be obtained to meet the needs of high-precision soldering, and there is no need for roller pressing; in another embodiment, a precision roller press can be used to produce a flatter, uniform, non-warping ultra-thin soldering gasket.

Step S4: according to the application requirements, the ultra-thin soldering gasket can be cut into different sizes or may not be cut; then the ultra-thin soldering gaskets are packaged separately to ensure the product flatness.

An embodiment of the present application provides a soldering method based on the ultra-thin soldering gasket, including placing the ultra-thin soldering gasket between soldering surfaces to be soldered, generally, between a component to be packaged (for example, a chip to be packaged) and a substrate, and then performing reflow soldering to form a packaging structure. The above soldering method can be used not only in the packaging process of semiconductor devices, but also in the packaging process of other electronic devices, which is not limited herein. For example, in the SMT process that requires large-area soldering, the above soldering method can be used to solder the module chip to the substrate through reflow soldering to form a package structure. Specifically, in an insulated gate bipolar transistor (IGBT) module package, the above soldering method is used to solder a plurality of chips to a ceramic substrate, and the heat dissipation soldering area is larger, forming an insulated gate bipolar transistor (IGBT) module. The soldering surface is generally a metal surface, and for example, the metal surface is one of copper, nickel/gold and other solderable metals.

When using the ultra-thin soldering gasket for welding, one ultra-thin soldering gasket can be used singly, or two or more ultra-thin soldering gaskets can be stacked and used together; the ultra-thin soldering gasket can also be prepared into a structure containing a plurality of support sheets during the preparation process.

An embodiment of the present application provides a semiconductor device, and the semiconductor device can include a package structure soldered using the ultra-thin soldering gasket. For example, the semiconductor device is an integrated circuit chip package, and the semiconductor device is used in soldering a chip and a board, a chip and a chip, a board and a board, a module and a module, a chip and a module, or a board and a module together, or soldering any combination of a chip, a module, a board and a heat sink together; or the semiconductor device is a heat dissipation module of the integrated circuit chip package, and the semiconductor device is used in soldering a chip and a heat dissipation plate together: or the semiconductor device is an insulated gate bipolar transistor (IGBT) module or other semiconductor devices.

It should be noted that the coefficient of thermal expansion (CTE) of the soldering gasket of an embodiment of the present application can be adjusted at any point between the CTE values of the support metal and the solder according to the needs of package structure, so that the soldering can achieve the best reliability.

The features and performances of the present application will be described in further detail below with reference to embodiments.

An ultra-thin soldering gasket provided by some embodiments of the present application will be described in detail below, and the ultra-thin soldering gasket can be prepared by the following preparation method.
(1) A support sheet with holes was gotten, which had a length of 120 mm, a width of 120 mm, a thickness of 30 μm, a material of nickel (Ni), a hole size of 40 ™, and a hole space of 50 μm; then the support sheet was subjected to a surface treatment process.
(2) A solder Sn—Ag—Cu was heated to 280° C. and melted to form a solder liquid.
(3) The support sheet after the surface treatment process was immersed in the solder liquid vertically for 1 min.
(4) The support sheet with the solder liquid coated on the surface was removed out and cooled to obtain a flat, uniform, non-warping ultra-thin soldering gasket with a thickness of 60 μm.

An ultra-thin soldering gasket provided by some other embodiments of the present application will be described in detail below, and the ultra-thin soldering gasket can be prepared by the following preparation method.
(1) A support sheet with holes was gotten, which had a length of 120 mm, a width of 120 mm, a thickness of 30 μm, a material of iron (Fe), a hole size of 40 μm, and a hole space of 50 μm; then the support sheet was subjected to a surface treatment process.
(2) A solder Sn—Pb was heated to 240° C. and melted to form a solder liquid.
(3) The support sheet after the surface treatment process was immersed in the solder liquid vertically for 2 min.
(4) The support sheet with the solder liquid coated on the surface was removed out and cooled to obtain a gasket with a thickness of 120 μm.
(5) The gasket was pressed into a flat, uniform, non-warping ultra-thin soldering gasket with a thickness of 70 μm through a precision roller press.

An ultra-thin soldering gasket provided by some other embodiments of the present application will be described in detail below, and the ultra-thin soldering gasket can be prepared by the following preparation method.
(1) A support sheet with holes was gotten, which had a length of 120 mm, a width of 120 mm, a thickness of 20 μm, a material of iron-nickel alloy, a hole size of 30 μm, and a hole space of 40 μm; then the support sheet was subjected to a surface treatment process.
(2) A solder Sn—Ag—Cu was heated to 300° C. and melted to form a solder liquid.
(3) The support sheet after the surface treatment process was immersed in the solder liquid vertically for 5 min.
(4) The support sheet with the solder liquid coated on the surface was removed out and cooled to obtain a gasket with a thickness of 50 sm.
(5) The gasket was pressed into a flat, uniform, non-warping ultra-thin soldering gasket with a thickness of 40 μm through a precision roller press.

### Comparative Example 1

This comparative example provides a metal mesh-embedded solder strip, which was prepared by cold-pressing the metal mesh into the solder material. Due to process limitations, the solder strip had a thickness of 75 μm and a width of 0.030-4 inches. The metal mesh was a metal mesh woven from metal wire.

To sum up, the above embodiments of the present application provide the ultra-thin soldering gasket, the preparation method therefor, the soldering method and the semiconductor device. The gasket is flat and non-warping, the solder material is uniform, and the minimum single-layer thickness is only 30 μm, which can meet the needs of high-precision soldering.

Embodiments of the present application are described above and should not be used to limit the protection scope of the present application. For those skilled in the art, various modifications and changes may be made to the present application. Any modification, equivalent replacement, improvement, etc., which are within the spirit and principle of the present application, shall fall within the protection scope of the present application.

### INDUSTRIAL APPLICABILITY

The present application provides an ultra-thin soldering gasket, a preparation method therefor, a soldering method, and a semiconductor device. The ultra-thin soldering gasket includes an internal support structure and a solder layer which covers the surface of the internal support structure, and the solder layer is formed by uniformly coating a solder liquid to the surface of the internal support structure. The preparation method for the ultra-thin soldering gasket includes the following steps: immersing the internal support structure which has been subjected to a surface treatment process in a solder liquid, and then removing and cooling the same. The soldering method based on the above ultra-thin soldering gasket includes placing the ultra-thin soldering gasket between soldering surfaces to be soldered, and then performing reflow soldering to form a semiconductor device. The ultra-thin soldering gasket is flat and non-warping, the solder material is uniform, and the minimum single-layer thickness is only 5 μm, which can meet the needs of high-precision soldering.

Furthermore, it should be understood that the ultra-thin soldering gasket, the preparation method, the soldering method and the semiconductor device of the present application are reproducible and can be used in a variety of industrial applications. For example, the ultra-thin soldering gasket, the preparation method, the soldering method and the semiconductor device of the present application can be used in the field of soldering gaskets.

1. An ultra-thin soldering gasket, comprising an internal support structure and a solder layer which covers the surface of the internal support structure, wherein the solder layer is formed by uniformly coating a solder liquid to the surface of the internal support structure, and the solder layer has a lower melting point than the internal support structure.

2. The ultra-thin soldering gasket according to claim 1, wherein the internal support structure is a flat support sheet; optionally, a thickness of the support sheet is 3-450 μm.

3. The ultra-thin soldering gasket according to claim 1, wherein the ultra-thin soldering gasket has a flat structure; optionally, a single-layer thickness of the ultra-thin soldering gasket is 10-1000 sm.

4. The ultra-thin soldering gasket according to claim 1, wherein a material of the internal support structure is metal; optionally, the material of the internal support structure is one of copper, copper alloy, nickel alloy, iron alloy, iron-nickel alloy, iron-nickel-cobalt alloy and stainless steel.

5. The ultra-thin soldering gasket according to claim 2, wherein the support sheet is an imperforate support sheet.

6. The ultra-thin soldering gasket according to claim 2, wherein the support sheet is a perforated support sheet, and the perforated support sheet is formed by opening holes on an imperforate support sheet.

7. The ultra-thin soldering gasket according to claim 6, wherein a hole diameter of the hole is less than 200 μm, and a shape of the hole is a triangle, a square, a rectangle, a hexagon or an irregular shape.

8. The ultra-thin soldering gasket according to claim 2, wherein the support sheet is a mesh support sheet or a continuous support structure; optionally, the support sheet or the support structure is a mesh support sheet woven from metal wires of different diameters or woven from metal wires of different diameters and spherical structures.

9. The ultra-thin soldering gasket according to claim 1, wherein a solder of the solder layer is a solderable material; optionally, the solder is selected from one of tin, a tin-based solder, indium, an indium-based solder, gallium, a gallium-based solder, a tin-bismuth solder, a tin-indium solder and other soldering materials.

10. A preparation method for the ultra-thin soldering gasket according to claim 1, comprising following steps: immersing the internal support structure which has been subjected to a surface treatment process in a solder liquid, and then removing and cooling the same.

11. The preparation method for the ultra-thin soldering gasket according to claim 10, wherein the internal support structure is a flat support sheet, and the support sheet is immersed in the solder liquid by pushing the support sheet into the solder liquid along the direction perpendicular to the surface of the solder liquid, and an immersion time is selected from one second to a plurality of hours according to different materials;
and/or the surface treatment process of the support sheet comprising the following steps in sequence: ultrasonic cleaning with a cleaning liquid, drying, activating, water washing, solvent wetting and drying; optionally, the cleaning liquid is selected from one of IPA, ethanol, methane, acetone and other metal cleaning liquids; an acid-washing activation liquid used in the activating is an organic acid and/or an inorganic acid.

12. The preparation method for the ultra-thin soldering gasket according to claim 11, wherein two or more support sheets are stacked together and immersed in the solder liquid at the same time, and then removed out and cooled;
or the support sheet is repeatedly immersed in the solder liquid for a plurality of times, and then removed out and cooled.

13. The preparation method for the ultra-thin soldering gasket according to claim 10, further comprising roller pressing.

14. A soldering method based on the ultra-thin soldering gasket according to claim 1, comprising placing the ultra-thin soldering gasket between soldering surfaces to be soldered, and then performing reflow soldering to form a packaging structure.

15. The soldering method according to claim 14, wherein one ultra-thin soldering gasket is used singly, or two or more ultra-thin soldering gaskets are used by stacking together.

16. The soldering method according to claim 14, wherein the soldering surface is a metal surface, and optionally, the metal surface is one of copper, nickel/gold and other solderable metals.

17. A semiconductor device, comprising a package structure soldered using the ultra-thin soldering gasket according to claim 1.

18. The semiconductor device according to claim 17, wherein the semiconductor device is an integrated circuit chip package, and the semiconductor device is used in soldering a chip and a board, a chip and a chip, a board and a board, a module and a module, a chip and a module, or a board and a module together, or soldering any combination of a chip, a module, a board and a heat sink together;
or the semiconductor device is a heat dissipation module of the integrated circuit chip package, and the semiconductor device is used in soldering a chip and a heat dissipation plate;
or the semiconductor device is an IGBT module.
